(19) United States
(12) Patent Application Publication
(10) Pub. No.: US 2017/0111745 A1
(43) Pub. Date: Apr. 20, 2017

(54) ELECTRO-ACOUSTIC CONVERSION FILM AND DIGITAL SPEAKER

(71) Applicant: FUJIFILM Corporation, Tokyo (JP)

(72) Inventor: Tetsu MIYOSHI, Ashigara-kami-gun (JP)

(73) Assignee: FUJIFILM Corporation, Tokyo (JP)

(21) Appl. No.: 15/394,024

(22) Filed: Dec. 29, 2016

Related U.S. Application Data
(63) Continuation of application No. PCT/JP2015/068585, filed on Jun. 26, 2015.

(30) Foreign Application Priority Data
Jun. 30, 2014 (JP) 2014-134468

(51) Int. Cl. H04R 17/00; H01L 41/047; H01L 41/257; H01L 41/29; H01L 41/193; H04R 1/00; H01L 41/09

(52) U.S. Cl. CPC H04R 17/005; H04R 1/005; H01L 41/047; H01L 41/09; H01L 41/29; H01L 41/193; H01L 41/257

(57) ABSTRACT

Provided is an electro-acoustic conversion film that is suitably used for a digital speaker or the like, and that includes a polymer composite piezoelectric body formed by dispersing piezoelectric particles in a viscoelastic matrix formed of a polymer material having viscoelasticity at room temperature, and thin-film electrodes provided on both surfaces of the polymer composite piezoelectric body, in which at least one of the thin-film electrodes is divided into a plurality of regions having the same area, and the respective regions are coupled in parallel and grouped to correspond to a weight of each bit digit of a parallel PCM digital signal. Thus, an electro-acoustic conversion film by which a digital speaker in which reverberation or crosstalk between segments is suppressed is obtained is provided.

### CROSS-REFERENCE TO RELATED APPLICATIONS

This application is a Continuation of PCT International Application No. PCT/JP2015/068585 filed on Jul. 26, 2015, which claims priority under 35 U.S.C. §119(a) to Japanese Patent Application No. 2014-134468 filed on Jun. 30, 2014. The above application is hereby expressly incorporated by reference, in its entirety, into the present application.

### BACKGROUND OF THE INVENTION

1. Field of the Invention

The present invention relates to an electro-acoustic conversion film used in a digital acoustic device such as a digital speaker, and to a digital speaker using the same.

2. Description of the Related Art

A digital speaker is a speaker to which a digital signal (pulse) is directly input so as to obtain a conventional analog acoustic output. Here, an analog signal is sampled at regular intervals using a “sampling theorem”, and a pulse having a sample value is applied to the speaker and subjected to digital/analog conversion (D/A conversion).

An electrodynamic speaker using a permanent magnet essentially has a D/A conversion function, and a large number of digital speakers may be considered using the function.

In order to perform the D/A conversion, it is necessary to have an acoustic output value corresponding to all of sample values of an input pulse. Specifically, it is necessary to perform weighting of output up to 2^{N-1} for a speaker for a signal system having a pulse with a maximum of N bits. For example, in an 8-bit signal system, a weighted output change is required from a minimum value 2⁰ (=1) to a maximum value 2⁷ (=128).

For this weighting method, a “multi-unit scheme” and a “multi-voice coil scheme” are known.

The “multi-unit scheme” is a scheme of performing acoustic synthesis in a space using a total of n units each having a weight corresponding to one bit. On the other hand, the “multi-voice coil scheme” is a scheme of performing weighting in a voice coil execution winding length Ω.

However, in the “multi-unit scheme”, there is a problem, for example, in that a large number of electrodynamic speakers are required as the number of bits increases. Moreover, in the “multi-voice coil system”, there is a problem, for example, in that a loss of magnetic energy increases with a decrease in space factor as the number of bits increases.

On the other hand, a digital speaker using a piezoelectric speaker different from an electrodynamic speaker has been proposed.

For example, JP1984-95796A (JP-S59-95796A) and JP1984-95799A (JP-S59-95799A) describe a digital speaker including a vibration plate formed of a piezoelectric element between a pair of flat electrodes, in which one of the flat electrodes includes a plurality of unit electrodes radially divided at substantially a constant angle, and the unit electrodes are grouped so that an area is proportional to a weight of each bit digit of a digital signal.

Further, Journal of the Institute of Electrostatics Japan (Vol. 11 @ No. 3, 1987) pp. 150-157 discloses a digital speaker in which an area of an electrode deposited on a surface of a polymer piezoelectric material is concentrically divided into seven such that it increases in size twofold from a center to the outside.

### SUMMARY OF THE INVENTION

A piezoelectric element having a unimorph structure including a piezoelectric ceramic and a vibration plate, which is used in a digital speaker described in JP1984-95796A (JP-S59-95796A) or JP1984-95799A (JP-S59-95799A) generates sound waves through surface mechanical vibration. Therefore, high-bit realization is difficult because of a unique resonance frequency and a narrow frequency band. Further, in a digital speaker using a unimorph type piezoelectric element, reverberation is easily generated in pulse driving. Further, in the digital speaker using a unimorph type piezoelectric element, since crosstalk easily occurs between respective divided unit electrodes, there is a problem in that noise increases. The crosstalk between the unit electrodes is interference between the respective electrodes.

On the other hand, in a digital speaker described in Journal of the Institute of Electrostatics Japan (Vol. 11 @ No. 3, 1987) pp. 150-157, there is no problem caused by surface mechanical vibration since a vibration plate is not used.

However, since a polymer piezoelectric material represented by uniaxially stretched PVDF (polyvinylidene fluoride) used in a digital speaker described in the Journal of the Institute of Electrostatics Japan (Vol. 11 @ No. 3, 1987) pp. 150-157 has a loss tangent (Tan δ) which is as small as approximately 0.02, reverberation easily occurs and crosstalk between respective segments easily occurs in pulse driving. Accordingly, there is a problem in that noise increases. Between respective segments is between respective divided electrodes.

Further, in the case of uniaxially stretched PVDF, since there is an in-plane anisotropy in piezoelectric characteristics, for example, even when concentric segmentation is performed, vibration cannot concentrically occur. Accordingly, a digital speaker with good sound quality is not obtained.

An object of the present invention is to solve the problems of such a related art and to provide an electro-acoustic conversion film suitable for a digital speaker in which reverberation hardly occurs even when pulse driving is performed, and crosstalk between respective divided electrodes can be suppressed.

In JP2014-14063A, an electro-acoustic conversion film in which a piezoelectric ceramic is dispersed in a matrix having viscoelasticity at room temperature has been proposed.

This electro-acoustic conversion film has large frequency dispersion in an elastic modulus, and has hard behave with vibration in an audio band (100 Hz to 10 kHz) and soft behave with vibration of a few Hz or less. Further, this electro-acoustic conversion film has an appropriately large loss tangent with respect to vibration at all frequencies of 20 kHz or less, and the loss tangent in this audio band is as very large as 0.09 to 0.35.

The present invention realizes a high sound quality piezoelectric digital speaker in which noise caused by reverberation and crosstalk is reduced by using this electro-acoustic conversion film in a vibration plate of the digital speaker as a result of intensive studies focused on a loss tangent in an audio band of the electro-acoustic conversion film being very large.

The present invention provides an electro-acoustic conversion film suitable for a digital speaker in which reverberation hardly occurs even when pulse driving is performed, and crosstalk between respective divided electrodes can be suppressed, which uses this electro-acoustic conversion film, and a digital speaker using this electro-acoustic conversion film.

That is, the electro-acoustic conversion film of the present invention provides an electro-acoustic conversion film comprising a polymer composite piezoelectric body formed by dispersing piezoelectric particles in a viscoelastic matrix formed of a polymer material having viscoelasticity at room temperature, and thin-film electrodes provided on both surfaces of the polymer composite piezoelectric body, in which at least one of the thin-film electrodes is divided into a plurality of regions having the same area, and the respective regions are coupled in parallel and grouped to correspond to a weight of each bit digit of a parallel PCM digital signal, and

wherein a loss tangent (Tan δ) at 100 Hz to 10 kHz at a temperature of 0° C. to 50° C. is 0.09 to 0.35.

In the electro-acoustic conversion film of the present invention, it is preferable for a grouping in which the respective regions are grouped to correspond to the weight of the each bit digit of the parallel PCM digital signal to be performed so that the number of regions increases by 2ⁿ (n is a natural number increasing by 1 and including 0) to correspond to the weight of the bit digit of the parallel PCM digital signal.

Further, it is preferable for a division in which the respective regions are divided into the plurality of regions having the same area to be performed so that the plurality of regions are arranged in one direction, and for a grouping in which the respective regions are grouped to correspond to the weight of the each bit digit of the parallel PCM digital signal to be performed so that the regions are sequentially directed from a center in the arrangement direction to both outer sides in the arrangement direction.

Further, it is preferable for the plurality of divided regions of the electrode to be a plurality of regions divided at the same angles radially from the center.

Further, it is preferable for a division in which the respective regions are divided into the plurality of regions having the same area to be performed in straight lines passing through the center, and for the region to include two small regions that are point symmetrical to the center.

Further, it is preferable for the electro-acoustic conversion film to further comprise protective layers formed on both surfaces of the thin-film electrode.

Further, it is preferable for a maximum value at which a loss tangent (Tan δ) at a frequency of 1 Hz from dynamic viscoelasticity measurement of the polymer material is 0.5 or more to be present in a temperature range of 0° C. to 50° C.

Further, it is preferable for a storage elastic modulus (E′) at a frequency of 1 Hz from dynamic viscoelasticity measurement of the electro-acoustic conversion film to be 10 to 30 GPa at 0° C. and 1 to 10 GPa at 50° C.

Further, it is preferable for glass transition temperature at a frequency of 1 Hz of the polymer material to be 0° C. to 50° C.

Further, it is preferable for the polymer material to have a cyanoethyl group.

Further, it is preferable for the polymer material to be cyanoethylated polyvinyl alcohol.

Further, a digital speaker of the present invention provides a digital speaker using the electro-acoustic conversion film of the present invention.

According to the electro-acoustic conversion film of the present invention, even when pulse driving is performed by a parallel PCM digital signal, reverberation hardly occurs and crosstalk between the divided electrodes (between segments) also hardly occurs. Therefore, a high sound quality digital speaker in which noise is reduced can be obtained.

Further, according to the electro-acoustic conversion film of the present invention, a flexible digital speaker can be achieved and even when the flexible digital speaker is bent, a change in sound quality due to a curvature or a bending direction is small.

### BRIEF DESCRIPTION OF THE DRAWINGS

FIGS. 1A and 1B are conceptual views of an example of an electro-acoustic conversion film of the present invention, FIG. 1A is a plan view, and FIG. 1B is a cross-sectional view taken along a line b-b of FIG. 1A.

FIGS. 2A to 2H are conceptual diagrams illustrating an operation of the electro-acoustic conversion film illustrated in FIGS. 1A and 1B.

FIG. 3A is a graph illustrating dynamic viscoelasticity of the electro-acoustic conversion film illustrated in FIGS. 1A and 1B, and FIG. 3B is a master curve of the electro-acoustic conversion film illustrated in FIGS. 1A and 1B.

FIGS. 4A to 4E are conceptual diagrams illustrating an example of a method of manufacturing the electro-acoustic conversion film illustrated in FIGS. 1A and 1B.

FIGS. 5A to 5H are conceptual diagrams illustrating another example of the electro-acoustic conversion film of the present invention, and an operation thereof.

FIGS. 6A to 6H are conceptual diagrams illustrating still another example of the electro-acoustic conversion film of the present invention, and an operation thereof.

FIG. 7 is a conceptual view of a speaker produced in an embodiment of the present invention.

### DESCRIPTION OF THE PREFERRED EMBODIMENTS

Hereinafter, an electro-acoustic conversion film and a digital speaker of the present invention will be described in detail on the basis of preferred examples illustrated in the accompanying drawings.

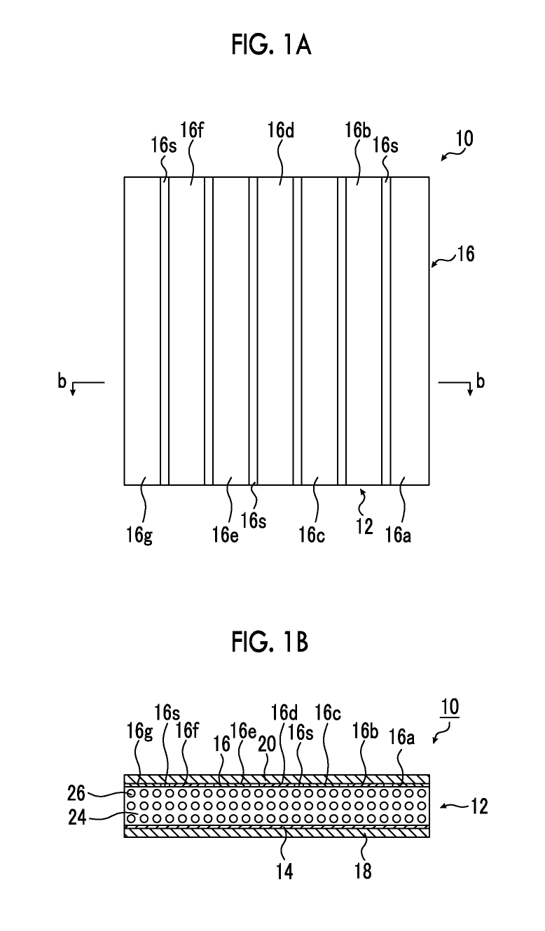

FIGS. 1A and 1B conceptually illustrate an example of the electro-acoustic conversion film of the present invention. In the following description, the electro-acoustic conversion film is also simply referred to as a conversion film.

FIG. 1A is a top view, and FIG. 1B is a sectional view taken along a line b-b of FIG. 1A. Further, in order to clearly illustrate a configuration of the conversion film, an upper protective layer 20 is omitted in FIG. 1A, and hatching is partially omitted in FIG. 1B.

The conversion film 10 illustrated in FIGS. 1A and 1B includes a piezoelectric layer 12, a lower thin-film electrode 14, an upper thin-film electrode 16, a lower protective layer 18, and an upper protective layer 20.

The lower thin-film electrode 14 is formed on one surface of the piezoelectric layer 12, and the upper thin-film electrode 16 is formed on a surface opposite to the lower thin-film electrode 14 of the piezoelectric layer 12. Further, the lower protective layer 18 is formed on the lower thin-film electrodes 14 (surface), and the upper protective layer 20 is formed on the upper thin-film electrode 16.

Further, the upper electrode 16 is divided into seven regions including regions 16a to 16g having the same area. In the example illustrated in FIG. 1A, the regions 16a to 16g are arranged in one direction and divided.

Further, in the upper electrode 16, the respective regions are coupled in parallel and grouped. Specifically, the region 16d is grouped as one region without being coupled in parallel to the other areas, the region 16c and the region 16e are coupled in parallel and grouped, and the region 16a, the region 16b, the region 16f, and the region 16g are coupled in parallel. This will be described below in detail.

Wirings are connected to the lower thin-film electrode 14 and the upper thin-film electrode 16 of such a conversion film 10, and an amplifier for driving is connected to the wirings to constitute the digital speaker of the present invention. In the upper thin-film electrodes 16, a wiring is connected to each group (segment) of the upper thin-film electrode 16.

The connection of the wirings to the lower thin-film electrodes 14 and the upper thin-film electrode 16 may be performed using a known method of connecting wirings for driving to thin-film electrodes. Further, for the amplifier for driving, various known amplifiers for reproducing a PCM digital signal used in a digital speaker are available.

In the conversion film 10, the piezoelectric layer 12 is formed of a polymer composite piezoelectric body.

In the present invention, the piezoelectric layer 12, that is, the polymer composite piezoelectric body is obtained by dispersing piezoelectric particles 26 in a viscoelastic matrix 24 formed of a polymer material having viscoelasticity at room temperature, as illustrated in 1B. As will be described below, the piezoelectric layer 12 is preferably polarized.

In this specification, the “room temperature” refers to a temperature range of about 0° C. to 50° C.

The conversion film 10 of the present invention is suitably used for a digital speaker having flexibility, such as a digital speaker for a flexible display. Here, it is preferable for the polymer composite piezoelectric body (piezoelectric layer 12) used in a digital speaker having flexibility to have the following characteristics:

(i) Flexibility

For example, when a conversion film is gripped in a state where the conversion film is loosely bent with a paper sense like a newspaper or a magazine that is portable, the conversion film is constantly subjected to large bending deformation that is relatively slow at a few Hz or less from the outside. In this case, when a polymer composite piezoelectric body is rigid, large bending stress is correspondingly generated, cracks occur at an interface between a polymer matrix and piezoelectric particles, and the polymer composite piezoelectric body may be eventually destructed. Thus, appropriate softness is required for a polymer composite piezoelectric body. Further, if strain energy can be diffused as heat to the outside, a stress can be relaxed. Therefore, an appropriately great loss tangent of the polymer composite piezoelectric body is required.

(ii) Sound Quality

In a speaker, piezoelectric particles are vibrated at a frequency in an audio band of 20 Hz to 20 kHz, an entire vibration plate (polymer composite piezoelectric body) is integrally vibrated by vibration energy, and sound is reproduced. Therefore, appropriate hardness is required in the polymer composite piezoelectric body in order to increase transmission efficiency of the vibration energy. Further, if a frequency characteristic of the speaker is smooth, the amount of change in the sound quality when a lowest resonance frequency f₀ is changed due to a change in curvature is also reduced. Therefore, an appropriately great loss tangent of the polymer composite piezoelectric body is required.

In summary, a polymer composite piezoelectric body used in a speaker having flexibility is required to has hard behave with vibration at 20 Hz to 20 kHz and soft behave with vibration at several Hz or less. Further, an appropriate great loss tangent of the polymer composite piezoelectric body against vibration at all frequencies of 20 kHz or less is required.

In general, a solid polymer has a viscoelasticity relaxation mechanism, and a molecular motion of a large scale with temperature increase or frequency decrease is observed as a decrease (relaxation) in a storage elastic modulus (Young's modulus) or a maximum (absorption) of a loss elastic modulus. Particularly, relaxation caused by Micro-Brownian motion of molecular chains of an amorphous region is referred to as main dispersion, and a very large relaxation phenomenon is observed. Temperature at which the main dispersion occurs is a glass transition point (Tg), and a most viscoelasticity relaxation mechanism appears conspicuously.

In the polymer composite piezoelectric body (piezoelectric layer 12), a polymer material having a glass transition point at room temperature, in other words, by using a polymer material having viscoelasticity at room temperature in a matrix, a polymer composite piezoelectric body that has hard behave with vibration at 20 Hz to 20 kHz and soft behave with slow vibration at several Hz or less is realized. In particular, it is preferable for the polymer material in which the glass transition temperature at a frequency of 1 Hz is at room temperature to be used in a matrix of the polymer composite piezoelectric body, for example, in that such a behavior is suitably expressed.

Various known materials are available as the polymer material having viscoelasticity at room temperature. Preferably, a polymer material in which a maximum value of the loss tangent Tan δ at a frequency of 1 Hz by dynamic viscoelasticity test is 0.5 or more at room temperature is used.

Thus, when the polymer composite piezoelectric body is slowly bent by external force, stress concentration of a polymer matrix/piezoelectric particle interface in a maximum bending moment portion is mitigated, and high flexibility can be expected.

Further, it is preferable for a storage elastic modulus (E′) at a frequency of 1 Hz due to dynamic viscoelasticity measurement of the polymer material to be 100 MPa or more at 0° C. and 10 MPa or less at 50° C.

Accordingly, a bending moment that is generated when the polymer composite piezoelectric body is slowly bent due to external force can be reduced, and the polymer composite piezoelectric body can has hard behave with acoustic vibration at 20 Hz to 20 kHz.

Further, it is more preferable for a relative dielectric constant of the polymer material to be 10 or more at 25° C. Thus, when a voltage is applied to the polymer composite piezoelectric body, a higher electric field is applied to the piezoelectric particles in the polymer matrix. Accordingly, a large deformation amount can be expected.

However, on the other hand, if ensuring of excellent moisture resistance is considered, it is preferable for the relative dielectric constant of the polymer material to be 10 or less at 25° C.

As polymer materials satisfying such conditions, cyanoethylated polyvinyl alcohol (cyanoethylated PVA), polyvinyl acetate, polyvinylidene chloride co-acrylonitrile, polystyrene-vinyl polyisoprene block copolymer, polyvinyl methyl ketone, and polybutyl methacrylate, and the like are exemplified. Moreover, as the polymer materials, commercially available products such as HYBRAR-5127 (manufactured by Kuraray Co., Ltd.) are also suitably available. Among them, a polymer material having a cyanoethyl group is preferably used, and the cyanoethylated PVA is more preferably used.

The polymer materials may be used alone, or a plurality of kinds of polymer materials may be used in combination (mixture).

The viscoelastic matrix 24 using such a polymer material having viscoelasticity at room temperature, a plurality of polymer materials may be used in combination, if necessary.

That is, other dielectric polymer materials may be added to the viscoelastic matrix 24, in addition to the viscoelastic material such as cyanoethylated PVA, for the purpose of adjustment of the dielectric properties or mechanical properties, if necessary.

As the dielectric polymer materials that can be added, fluorinated polymer such as polyvinylidene fluoride, vinylidene fluoride-tetrafluoroethylene copolymer, vinylidene fluoride-trifluoroethylene copolymer, polyvinylidene fluoride-trifluoroethylene copolymer, and polyvinylidene fluoride-tetrafluoroethylene copolymer, polymer having cyano groups such as vinylidene cyanide-vinyl acetate copolymer, cyanoethyl cellulose, cyanoethyl hydroxye sucrose, cyanoethyl hydroxy cellulose, cyanoethyl hydroxy pullulan, cyanoethyl methacrylate, cyanoethyl acrylate, cyanoethyl hydroxyethyl cellulose, cyanoethyl amylose, cyano ethyl hydroxypropyl cellulose, cyanoethyl dihydroxypropyl cellulose, cyanoethyl hydroxypropyl amylose, cyanoethyl polyacrylamide, cyanoethyl polyacrylate, cyanoethylpullulan, cyanoethyl polyhydroxymethylene, cyano ethyl glycidol pullulan, cyanoethyl sucrose, and cyanoethyl sorbitol, or cyanoethyl groups, synthetic rubber such as nitrile rubber or chloroprene rubber, and the like are exemplified.

Among them, the polymer material having a cyanoethyl group is suitably utilized.

Further, in the viscoelastic matrix 24 of the piezoelectric layer 12, dielectric polymer added in addition to the material having viscoelasticity at room temperature, such as cyanoethylated PVA, is not limited to one kind of polymer, and a plurality of kinds of polymers may be added.

Further, in order to adjust a glass transition point Tg, a thermoplastic resin such as a vinyl chloride resin, polyethylene, polystyrene, a methacrylic resin, polybutene or isobutylene, or a thermosetting resin such as a phenol resin, an urea resins, a melamine resin, an alkyd resin or mica may be added, in addition to the dielectric polymer.

Further, in order to improve adhesiveness, a viscosity imparting agent such as rosin ester, rosin, terpene, terpene phenol, or a petroleum resin may be added.

In the viscoelastic matrix 24 of the piezoelectric layer 12, an addition amount when a polymer other than a material having viscoelasticity at room temperature, such as cyanoethylated PVA, is added is not particularly limited, and a percentage in the viscoelastic matrix 24 is preferably 30% by mass or less.

Thus, it is possible to obtain desirable results, for example, in terms of a high dielectric constant, improved heat resistance, or improved adhesion to the piezoelectric particles 26 or the electrode layer since characteristics of the polymer material to be added can be expressed without impairing a viscoelasticity relaxation mechanism in the viscoelastic matrix 24.

In the piezoelectric layer 12, the piezoelectric particles 26 are dispersed in the viscoelastic matrix 24.

For the piezoelectric particles 26, various particles formed of a known piezoelectric body are available, but particles formed of ceramic particles having a perovskite or wurtzite crystal structure are preferably exemplified.

As the ceramic particles constituting the piezoelectric particles 26, specifically, lead zirconate titanate (PZT), lanthanum zirconate titanate lead (PLZT), barium titanate (BaTiO₃), zinc oxide (ZnO), and a solid solution (BFBT) of barium and bismuth ferrite titanate (BiFe₃) are preferably exemplified.

A particle size of the piezoelectric particles 26 may be appropriately selected according to a size or a use of the conversion film 10. According to the study of the present inventors, the particle size of the piezoelectric particles 26 is preferably 1 to 10 μm.

When the particle size of the piezoelectric particles 26 is in the above range, it is possible to obtain preferable results, for example, in that both of high piezoelectric characteristics and flexibility can be achieved.

In FIG. 1B, the piezoelectric particles 26 in the piezoelectric layer 12 are distributed with regularity in the viscoelastic matrix 24, but the present invention is not limited thereto.

That is, although the piezoelectric particles 26 in the piezoelectric layer 12 are preferably homogeneously dispersed, the piezoelectric particles 26 may be randomly dispersed in the viscoelastic matrix 24.

In the conversion film 10 of the present invention, an amount ratio of the viscoelastic matrix 24 and the piezoelectric particles 26 in the piezoelectric layer 12 may be appropriately set according to a size or a thickness of the conversion film 10, a use of the conversion film 10, characteristics required for the conversion film 10, or the like. The size of the conversion film 10 is a size in a surface direction of the conversion film 10.

Here, according to study of the present inventors, a volume fraction of the piezoelectric particles 26 in the piezoelectric layer 12 is preferably 30% to 70%, particularly preferably 50% or more, and therefore, more preferably 50% to 70%.

When the amount ratio between the viscoelastic matrix 24 and the piezoelectric particles 26 is in the above range, it is possible to obtain preferable results, for example, in that both of high piezoelectric characteristics and flexibility can be achieved.

Further, in the conversion film 10 of the present invention, the thickness of the piezoelectric layer 12 is not particularly limited and may be appropriately set according to a size of the conversion film 10, use of the conversion film 10, characteristics required for the conversion film 10, or the like.

Here, according to the study of the present inventors, the thickness of the piezoelectric layer 12 is preferably 10 μm to 300 μm, more preferably 20 to 200 μm, and particularly preferably 30 to 100 μm.

When the thickness of the piezoelectric layer 12 is in the above range, it is possible to obtain preferable results, for example, in that both of ensuring of rigidity and appropriate flexibility can be achieved.

The piezoelectric layer 12 is preferably subjected to a polarization process (polling) as described above. The polarization process will be described in detail below.

As illustrated in FIG. 1B, in the conversion film 10 of the present invention, the lower thin-film electrode 14 is formed on one surface of the piezoelectric layer 12, and the upper thin-film electrode 16 is formed on the other surface of the piezoelectric layer 12. Further, the lower protective layer 18 is formed on the lower thin-film electrode 14, and the upper protective layer 20 is formed on the upper thin-film electrode 16.

That is, the conversion film 10 has a configuration in which piezoelectric layer 12 is sandwiched between the lower thin-film electrode 14 and the upper thin-film electrode 16, and this laminated body is sandwiched between the lower protective layer 18 and the upper protective layer 20.

Here, the upper electrode 16 is divided into seven regions including regions 16a to region 16g that are arranged in one direction (lateral direction in the figure) and have the same area. Further, in the upper electrode 16, the central region 16d is grouped in one region without being coupled in parallel to the other regions, the two regions including the region 16c and the region 16e on the both sides thereof are coupled in parallel and grouped, and the four outer regions including the region 16a, the region 16b, the region 16f, and the region 16g are coupled in parallel and grouped.

Hereinafter, the grouped regions are also referred to as a segment. Further, the group including only the region 16d is referred to as a first segment, the group including the region 16c and the region 16e is referred to as a second segment, and the group including the region 16a, the region 16b, the region 16f, and the region 16g is referred to as a third segment.

On the other hand, the lower electrode 14 serves as an electrode common to all the regions, that is, the segments of the upper electrode 16.

Accordingly, driving power is individually supplied to the respective regions constituting the first segment, the second segment, and the third segment to individually drive the piezoelectric layer 12 in the corresponding regions. Thus, sound can be output.

Further, the number of regions constituting the respective segments of the upper electrode 16 increases 2ⁿ times to correspond to each bit digit of a parallel PCM digital signal. Thus, the conversion film 10 can output D/A-converted reproduction sound according to the supplied parallel PCM digital signal.

Further, the piezoelectric layer 12 is a layer in which the piezoelectric particles 26 are dispersed in the viscoelastic matrix 24 formed of a polymer material having viscoelasticity at room temperature. Therefore, even when each segment of the upper electrode 16 is pulse-driven, reverberation is less and crosstalk in which vibrations of the respective segments interfere with each other is less. This will be described in detail below.

In the conversion film 10 of the illustrated example, the lower electrode 14 is a common electrode corresponding to all regions including the region 16a to the region 16 g. That is, the lower electrode 14 is an electrode common to all the three segments.

However, in the conversion film of the present invention, the lower electrode 14 may also be divided to correspond to each region or each segment of the upper electrode 16. Alternatively, the lower electrode 14 may be divided into, for example, an electrode common to the two segments of the upper electrode and an electrode corresponding to the one segment.

Further, planar shapes of the upper electrode and the lower electrode may be different. For example, the upper electrode is circular and the lower electrode is rectangular.

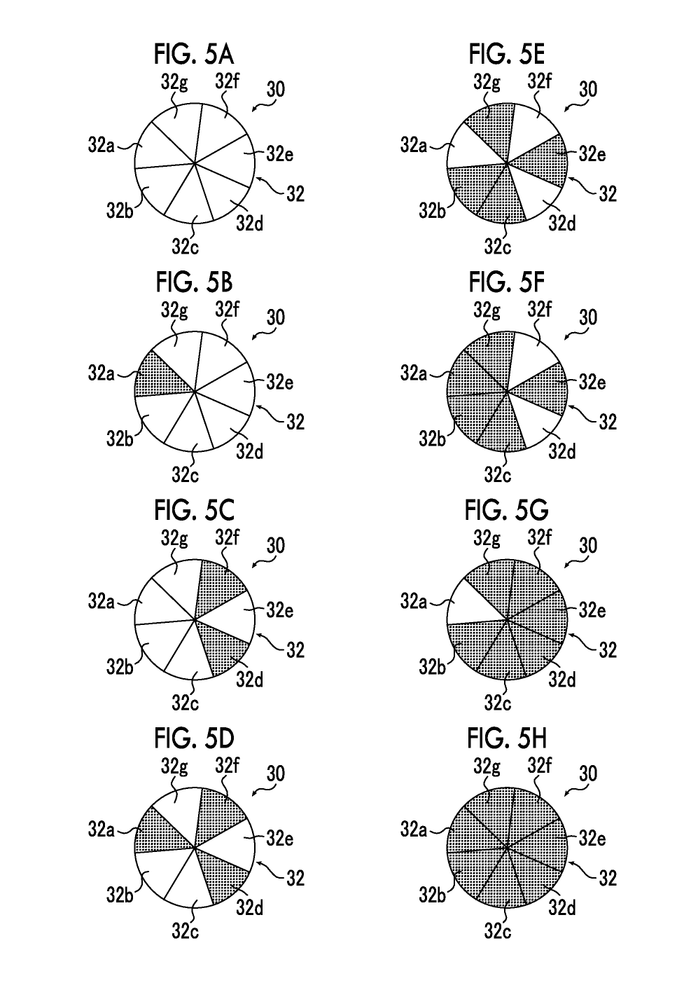

The same applies to each conversion film illustrated in, for example, FIG. 5A, 6A, and the like to be described below.

In the conversion film 10, the lower protective layer 18 and the upper protective layer 20 impart appropriate rigidity and mechanical strength to the piezoelectric layer 12.

In the conversion film 10 of the present invention, the piezoelectric layer 12 formed of the viscoelastic matrix 24 and the piezoelectric particles 26 shows very excellent flexibility with respect to slow bending deformation. On the other hand, the piezoelectric layer 12 may have insufficient rigidity and mechanical strength in some applications. In the conversion film 10, the lower protective layer 18 and the upper protective layer 20 are provided as a preferred aspect in order to compensate for synthesis or mechanical strength.

The lower protective layer 18 and the upper protective layer 20 are not particularly limited, and various sheet-like objects are available.

For example, various resin films (plastic films) are preferably exemplified. Particularly, polyethylene terephthalate (PET), polypropylene (PP), polystyrene (PS), polycarbonate (PC), polyphenylene sulfide (PPS), polymethyl methacrylate (PMMA), polyetherimide (PEI), polyimide (PI), polyethylene naphthalate (PEN), triacetyl cellulose (TAC), or a cyclic olefin resin is preferably used because of, for example, excellent mechanical properties and heat resistance thereof.

Thicknesses of the lower protective layer 18 and the upper protective layer 20 are not particularly limited. Further, although the thicknesses of the lower protective layer 18 and the upper protective layer 20 are basically the same, the thicknesses may be different.

Here, if the rigidity of the lower protective layer 18 and the upper protective layer 20 is too high, expansion and contraction of the piezoelectric layer 12 are restrained and flexibility is also impaired. Accordingly, the lower protective layer 18 and the upper protective layer 20 are advantageously thinner except that mechanical strength or good handlability of a sheet-like object is required.

According to the study of the present inventors, if the thicknesses of the lower protective layer 18 and the upper protective layer 20 are equal to or smaller than twice the thickness of the piezoelectric layer 12, it is possible to obtain preferable results, for example in that both of ensuring of rigidity and appropriate flexibility are achieved.

For example, if the thickness of the piezoelectric layer 12 is 50 μm and the lower protective layer 18 and the upper protective layer 20 are formed of PET, the thicknesses of the lower protective layer 18 and the upper protective layer 20 are preferably 100 μm or less, more preferably 50 μm or less, and particularly preferably, 25 μm or less.

In the conversion film 10 of the present invention, the lower thin-film electrode 14 is formed between the piezoelectric layer 12 and the lower protective layer 18, and the upper thin-film electrode 16 is formed between the piezoelectric layer 12 and the upper protective layer 20. In the following description, the lower thin-film electrode 14 is also referred to as the lower electrode 14. In the following description, the upper thin-film electrode 16 is also referred to as the upper electrode 16.

The lower electrode 14 and the upper electrode 16 are provided in order to apply an electric field to the piezoelectric layer 12 to expand and contract the piezoelectric layer 12 in a region corresponding to each segment of the upper electrode 16 and output sound.

In the present invention, a material for forming the lower electrode 14 and the upper electrode 16 is not particularly limited, and various conductors are available. Specifically, carbon, palladium, iron, tin, aluminum, nickel, platinum, gold, silver, copper, chromium, molybdenum, an alloy thereof, indium tin oxide, or the like is exemplified. Among them, any one of the copper, the aluminum, the gold, the silver, the platinum, and the indium tin oxide is preferably exemplified.

Further, a method of forming the lower electrode 14 and the upper electrode 16 is not particularly limited, and various known methods such as a vapor deposition method (a vacuum film formation method) such as vacuum deposition or sputtering, film formation using plating, or a method of adhering a foil formed of the above material are available.

In particular, a thin film of copper or aluminum formed by vacuum evaporation is preferably used as the lower electrode 14 and the upper electrode 16, for example, since the flexibility of the conversion film 10 can be ensured. Particularly, the thin film of copper formed by the vacuum deposition is preferably used.

Thicknesses of the lower electrode 14 and the upper electrode 16 are not particularly limited. Although the thicknesses of the lower electrode 14 and the upper electrode 16 are basically equal, the thicknesses may be different.

Here, if the rigidity of the lower electrode 14 and the upper electrode 16 is too high, expansion and contraction of the piezoelectric layer 12 are restrained and flexibility is also impaired, similar to the lower protective layer 18 and the upper protective layer 20 described above. Accordingly, the lower electrode 14 and the upper electrode 16 are advantageously thinner as long as electrical resistance is not too high.

Here, according to the study of the present inventor, it is preferable that a product of the thickness of the lower electrode 14 and the upper electrode 16 and a Young's modulus is smaller than a product of the thickness of the lower protective layer 18 and the upper protective layer 20 and a Young's modulus, since flexibility is not greatly impaired.

For example, when the lower protective layer 18 and the upper protective layer 20 are PET (Young's modulus: about 6.2 GPa) and the lower electrode 14 and the upper electrode 16 are copper (Young's modulus: 130 GPa), if the thickness of the lower protective layer 18 and the upper protective layer 20 is 25 μm, the thickness of the lower electrode 14 and the upper electrode 16 is preferably 1.2 μm or less, more preferably 0.3 μm or less, and particularly preferably 0.1 μm or less.

As described above, the conversion film 10 of the present invention has a configuration in which the piezoelectric layer 12 (polymer composite piezoelectric body) formed by dispersing the piezoelectric particles 26 in the viscoelastic matrix 24 having viscoelasticity at room temperature is sandwiched by the lower electrode 14 and the upper electrode 16, and such a laminated body is sandwiched between the lower protective layer 18 and the upper protective layer 20.

In such a conversion film 10, it is preferable for a maximum value at which a loss tangent (Tan δ) at a frequency of 1 Hz from dynamic viscoelasticity measurement is equal to or greater than 0.1 to be present at room temperature.

Thus, since strain energy can be efficiently diffused as heat to the outside even when the conversion film 10 is subjected to large bending deformation that is relatively slow at several Hz or less from the outside, it is possible to prevent cracks from occurring at an interface between the polymer matrix and the piezoelectric particles.

A storage elastic modulus (E′) of the conversion film 10 at a frequency of 1 Hz from dynamic viscoelasticity measurement is preferably 10 to 30 GPa at 0° C. and 1 to 10 GPa at 50° C.

Thus, the conversion film 10 can have large frequency dispersion in the storage elastic modulus (E′) at room temperature. That is, the conversion film 10 can have hard behave with vibration of 20 Hz to 20 kHz and soft behave with vibration of a few Hz or less.

Further, in the conversion film 10, it is preferable for a product of the thickness and a storage elastic modulus (E′) at a frequency of 1 Hz from dynamic viscoelasticity measurement to be 1.0×10⁶ to 2.0×10⁶ (1.0E+06 to 2.0E+06) N/m at 0° C., and 1.0×10⁵ to 1.0×10⁶ (1.0E+05 to 1.0E+06) N/m at 50° C.

Thus, appropriate rigidity and mechanical strength are included in a range in which the conversion film 10 does not impair the flexibility and acoustical properties.

Further, in the conversion film 10, it is preferable for a loss tangent (Tan δ) at 25° C. and a frequency of 1 kHz to be 0.05 or more in a master curve obtained from dynamic viscoelasticity measurement.

Thus, a frequency characteristic of a speaker using the conversion film 10 becomes smooth, and an amount of change in sound quality when a lowest resonance frequency f₀ due to a change in curvature of the speaker is changed can be small.

As illustrated in FIG. 1A, the upper electrode 16 is divided into seven regions including the region 16a, the region 16b, the region 16c, the region 16d, the region 16e, the region 16f, and the region 16g that are arranged in one direction (lateral direction in the figure) and have the same area.

In the upper electrode 16, the respective regions are separated with a gap 16s not to be electrically connected to each other. The gap 16s between the respective regions is preferably 1 mm or more, and more preferably, 10 mm or more. The gap 16s between the respective regions is preferably 1 mm or more in that crosstalk between the segments can be prevented more suitably. The regions constituting the same segment may be in contact with each other. The gap 16s between the respective regions is a separation distance between the respective segments.

Further, an insulating layer may be provided between the respective regions, if necessary.

As described above, the respective regions of the upper electrode 16 are segments corresponding to a parallel PCM digital signal due to parallel coupling. That is, the respective regions of the upper electrode 16 are grouped to correspond to the parallel PCM digital signal due to parallel coupling.

Here, the number of regions divided in the upper electrode 16 is 2^{N-1} according to the maximum bit number N of the parallel PCM digital signal, and the number of segments is N corresponding to the maximum bit number N.

Further, the number of regions constituting each segment increases (is weighted) by 2ⁿ times to correspond to a weight of each bit digit of the parallel PCM digital signal. “2ⁿ times” is “n power of 2 times”, and n is a natural number increasing by 1 and including zero.

Thus, a largest segment is a segment of which the number of regions increases to 2ⁿ times with respect to a smallest segment according to the maximum bit number N of the conversion film. In other words, the largest segment is a segment in which the number of regions is weighted to 2^{N-1} times with respect to the smallest segment according to the maximum bit number N of the conversion film.

The area of each region is the same. Accordingly, the number of regions of the respective segments proportional to a weight of each bit digit of the parallel PCM digital signal is an area ratio of the respective segments proportional to the weight of each bit digit of the parallel PCM digital signal.

In the conversion film 10 of the illustrated example, in the upper electrode 16, for example, the respective segments are configured with the number that is proportional to a weight of each bit digit of a parallel PCM digital signal of 3 bit digits to correspond to an output of 3 bits. As known, the 3 bits are 8 gradations and correspond to audio output intensity of 8 steps).

That is, as described above, the upper electrode 16 is divided into seven regions including the regions 16a to 16g having the same area. Moreover, the first segment includes one (2⁰) region 16d that is not coupled in parallel to the other regions. Further, the second segment includes two (2¹) regions including the region 16c and the region 16e that are coupled in parallel. Further, the third segment includes four (2²) regions including the region 16a, the region 16b, the region 16f, and the region 16g that are coupled in parallel.

Here, as described above, since the respective regions have the same area, when the area of the first segment including one region is 1, the area of the second segment including two regions is 2, and the area of the third segment including four regions is 4. The area of each segment is an area proportional to the weight of each bit digit of the parallel PCM digital signal of 3 bit digits.

Accordingly, sound waves generated from the respective segments are added and combined in proportion to a weight of each bit digit by driving the first segment to the third segment of the upper electrode 16 in eight driving patterns in which the segment corresponding to each bit digit is indicated by a binary representation of 3 bits according to the 3-bit parallel PCM digital signal, and reproduction sound with eight gradations correctly subjected to the D/A conversion can be output.

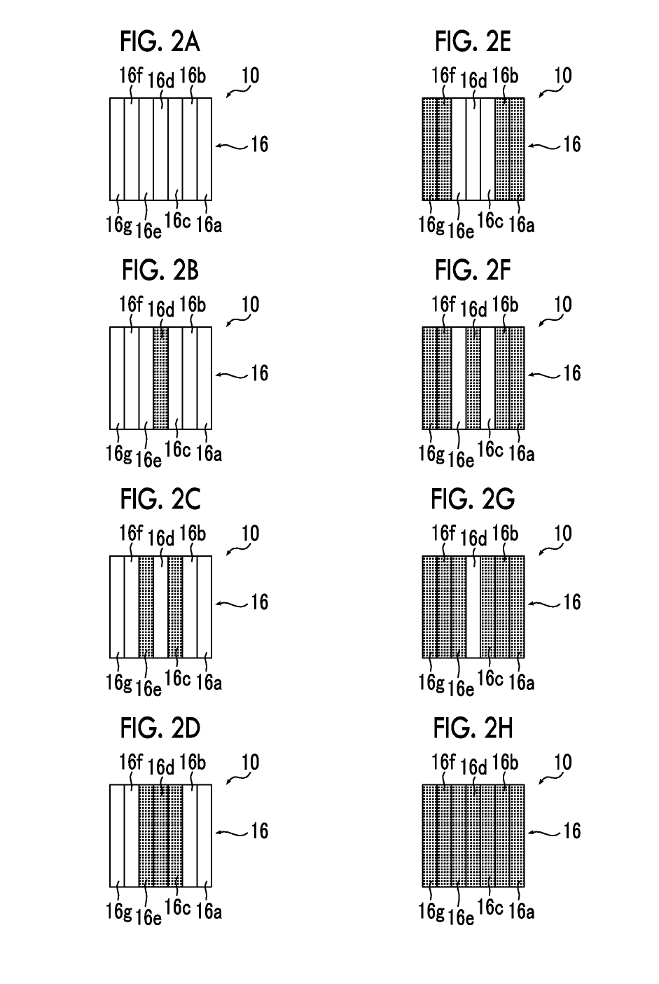

FIGS. 2A to 2H schematically illustrate an example of the method of driving the conversion film 10 according to the parallel PCM digital signal.

In FIGS. 2A to 2H, the upper protective layer 20 is omitted in order to clearly illustrate a configuration, and the gap between the regions is also omitted in order to simplify FIGS. 2A to 2H.

Further, in FIGS. 2A to 2H, the regions to be driven, that is, the segments to be driven are shaded.

In a case where the parallel PCM digital signal is “0”, any of the first segment to the third segment are not driven (0+0+0=0), as illustrated in FIG. 2A.

In a case where the parallel PCM digital signal is “1”, only the first segment, that is, the region 16d is driven (0+0+2⁰=1), as illustrated in FIG. 2B.

In a case where the parallel PCM digital signal is “2”, only the second segment, that is, the regions 16c and the regions 16e is driven (0+2¹+0=2), as illustrated in FIG. 2C.

In a case where the parallel PCM digital signal is “3”, the first segment, that is, the region 16d and the second segment, that is, the regions 16c and the regions 16e are driven (0+2¹+2⁰=3), as illustrated in FIG. 2D.

In a case where the parallel PCM digital signal is “4”, the third segment, that is, the region 16a, the region 16b, the region 16f, and the region 16g are driven (2²+0+0=4), as illustrated in FIG. 2E.

In a case where the parallel PCM digital signal is “5”, the first segment, that is, the region 16d and the third segment, that is, the region 16a, the region 16b, the region 16f, and the region 16g are driven (2²+0+2⁰=5), as illustrated in FIG. 2F.

In a case where the parallel PCM digital signal is “6”, the second segment, that is, the regions 16c and the regions 16e, and the third segment, that is, the region 16a, the region 16b, the region 16f, and the region 16g are driven (2²+2¹+0=6), as illustrated in FIG. 2G.

Further, in a case where the parallel PCM digital signal is “7”, the first segment, that is, the region 16d, the second segment, that is, the regions 16c and the regions 16e, and the third segment c, that is, the region 16a, the region 16b, the region 16f, and the region 16g are all driven (2²+2¹+2⁰=7), as illustrated in FIG. 2H.

Thus, audio output subjected to D/A conversion with intensity of 8 gradations including 0 to 7 gradations according to the 3-bit parallel PCM digital signal can be performed.

Here, as described above, in the conversion film 10 of the present invention, the polymer composite piezoelectric body in which the piezoelectric particles 26 are dispersed in the viscoelastic matrix 24 formed of a polymer material having viscoelasticity at room temperature is used as the piezoelectric layer 12.

As described above, this conversion film 10 has large frequency dispersion in the elastic modulus, and has hard behave with vibration in an audio band (100 Hz to 10 kHz) at room temperature and soft behave with vibration of a few Hz or less. Further, this conversion film 10 has an appropriately great loss tangent with respect to the vibration at all of the frequencies of 20 kHz or less at room temperature, and the loss tangent in an audio band is as very great as 0.09 to 0.35.

Therefore, a digital speaker using the conversion film 10 as a vibration plate can perform high-quality reproduction in a wide frequency band, and even when a parallel PCM digital signal is reproduced, interference of vibration between the respective segments is very small.

Further, the conversion film 10 immediately increases audio output according to ON of the parallel PCM digital signal and immediately stops the audio output according to OFF. That is, in the conversion film 10, reverberation is very small.

Therefore, according to the conversion film 10 (digital speaker) of the present invention, the parallel PCM digital signal can be suitably reproduced in each segment.

Further, according to the conversion film 10 of the present invention, a flexible digital speaker can be achieved and even when the electro-acoustic conversion film is bent, a change in sound quality due to a curvature or a direction of bending is small.

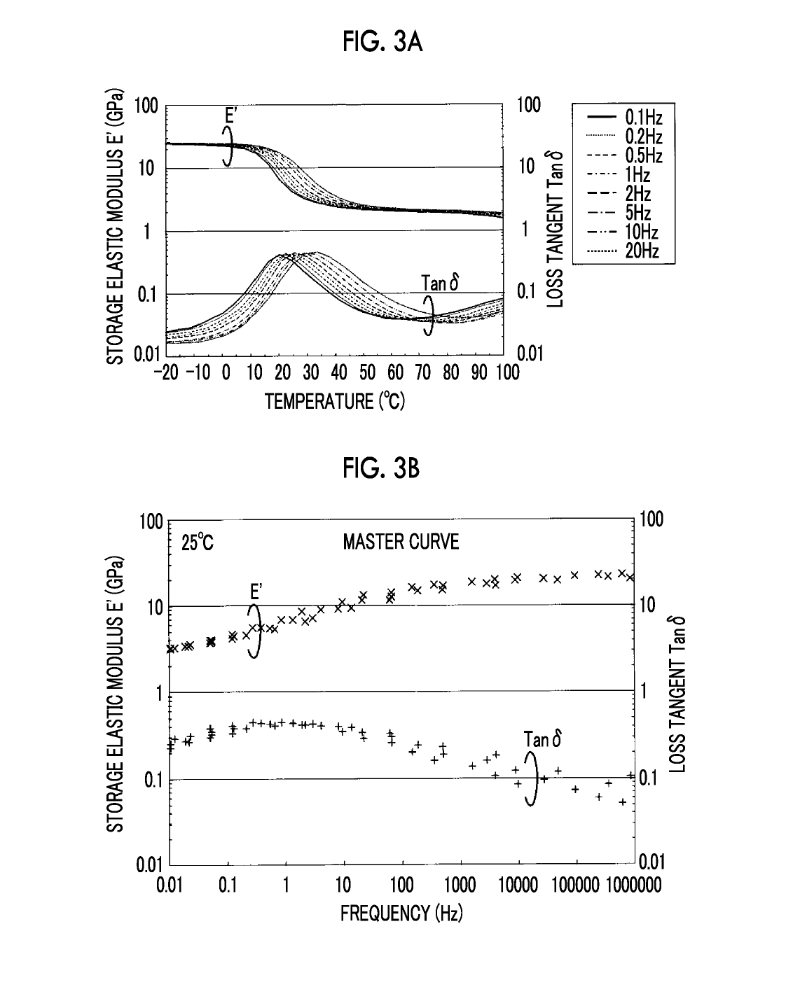

In FIG. 3A, a result of measuring temperature dependency of dynamic viscoelasticity after a test piece of the conversion film 10 is produced is illustrated. Further, in FIG. 3B, a master curve at a reference temperature of 25° C. obtained from such a dynamic viscoelasticity measurement is illustrated.

The master curve shows frequency distribution of a viscoelastic property at a certain temperature. In general, there is a certain relationship based on a “time-temperature conversion rule” between a frequency and a temperature in a dynamic viscoelasticity measurement result. For example, a change in temperature can be converted into the change in frequency, and the frequency dispersion of the viscoelastic property at a certain temperature can be examined. A curve created at that time is referred to as a master curve. Since viscoelasticity measurement in an actual audio band such as 1 kHz is not realistic, the master curve is effective in understanding a storage elastic modulus E′ or a loss tangent Tan δ of a material in the audio band.

The graphs illustrated in FIGS. 3A and 3B are measured by performing the following test using the test piece of the conversion film produced using a method described in an embodiment to be described below.

[Dynamic Viscoelasticity Test]

A strip-shaped test piece of 1 cm×4 cm was prepared from a prepared conversion film.

The dynamic viscoelasticity (storage elastic modulus E′(GPa) and the loss tangent Tan δ) of the test piece was measured using a dynamic viscoelasticity tester (SII Nanotechnology DMS6100 viscoelasticity spectrometer). Measurement conditions were as follows.

Measurement temperature range: −20° C. to 100° C.

Rate of temperature rise: 2° C./minute

Measurement frequency: 0.1 Hz, 0.2 Hz, 0.5 Hz, 1.0 Hz, 2.0 Hz, 5.0 Hz, 10 Hz, and 20 Hz

Measurement mode: tension measurement

The conversion film 10 of the present invention has a region to which no signal is applied between the segments. The region to which no the signal is applied between the segments is the gap 16s and is a division region that divides the respective segments.

This division region always exhibits rheological properties at a frequency of 0 Hz. Here, as illustrated in FIG. 3B, in the conversion film 10, when a frequency is approximately 0 Hz, the loss tangent (loss tangent Tan δ) is great and a storage elastic modulus E′ is small. Accordingly, sound velocity is low. Therefore, it is possible to cancel vibrations from the respective segments in this separation region and to prevent the vibration of one segment from propagating to the other segment. Therefore, even when different signals are input to the respective segments and reproduced, it is possible to suitably reproduce an acoustic signal in the respective regions without vibrations of the respective segments interfering with each other.

Further, the vibration starts immediately according to application of a voltage and, when driving stops, the vibration immediately stops. That is, the reverberation is less.

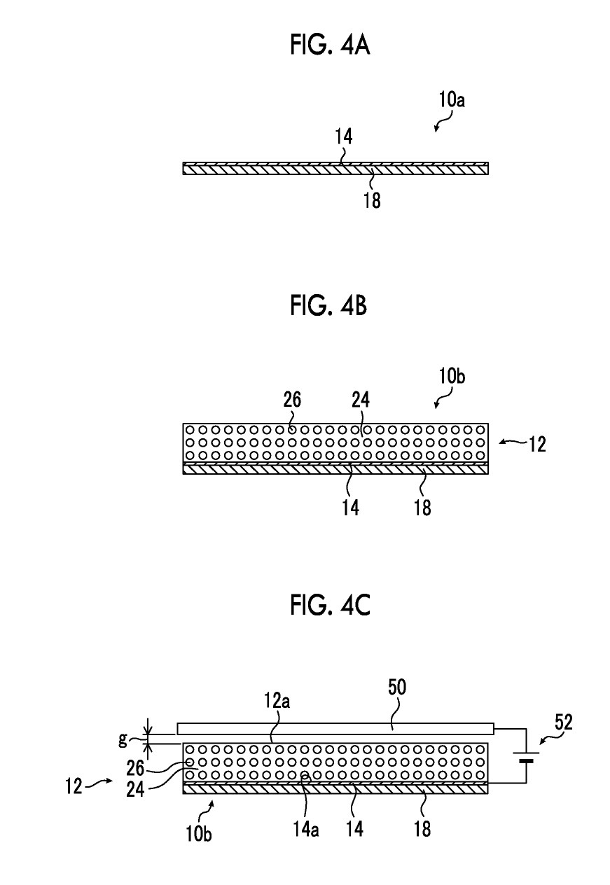

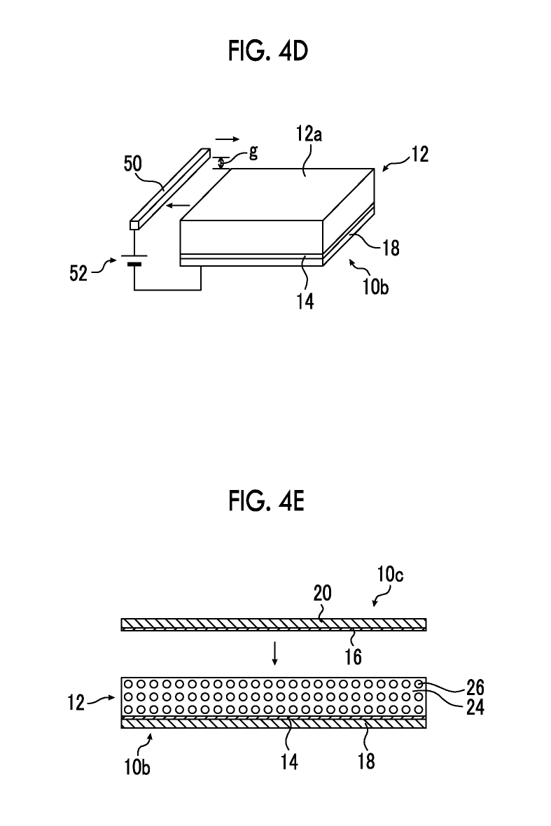

Hereinafter, an example of a method of manufacturing the conversion film 10 will be described with reference to conceptual diagrams of FIGS. 4A to 4E.

First, as illustrated in FIG. 4A, a sheet-like object 10a in which the lower electrode 14 is formed on the lower protective layer 18 is prepared.

This sheet-like object 10a may be produced by forming a copper thin film or the like serving as the lower electrode 14 on a surface of the lower protective layer 18 using vacuum deposition, sputtering, plating, or the like. Alternatively, a commercially available product in which a copper thin film or the like is formed on the lower protective layer 18 may be used as the sheet-like object 10a.

On the other hand, a polymer material having viscoelasticity at room temperature, such as cyanoethylated PVA, is dissolved in an organic solvent, piezoelectric particles 26 such as PZT particles are added, and a coating material obtained by stirring and dispersing is prepared. In the following description, a polymer material having viscoelasticity at room temperature is also referred to as a viscoelastic material.

The organic solvent is not particularly limited, and various organic solvents such as dimethylformamide (DMF), methyl ethyl ketone, and cyclohexanone are available.

After the sheet-like object 10a is prepared and the above-described coating material is prepared, the coating material is cast (coated) to the sheet-like object 10a, the organic solvent is evaporated, and drying is performed. Thus, as illustrated in FIG. 4B, the lower electrode 14 is included on the lower protective layer 18, and the piezoelectric layer 12 is formed on the lower electrode 14 to prepare a laminated body 10b.

A method of casting the coating material is not particularly limited, and known coating methods (coating devices) such as a slide coater and a doctor knife are all available.

Alternatively, if the viscoelastic material is a thermally meltable material such as cyanoethylated PVA, the following method is available. First, a molten material is prepared by heating and melting a viscoelastic material and adding/dispersing the piezoelectric particles 26 to the viscoelastic material. The molten material is extruded in a sheet shape on the sheet-like object illustrated in FIG. 4A using extrusion molding or the like and is cooled. Thus, a laminated body 10b formed by forming the lower electrode 14 on the lower protective layer 18 and forming the piezoelectric layer 12 on the lower electrode 14 may be prepared, as illustrated in FIG. 4B.

In the conversion film 10 of the present invention, a polymer piezoelectric material such as PVDF may be added to the viscoelastic matrix 24, in addition to the viscoelastic material, such as the cyanoethylated PVA, as described above.

When the polymer piezoelectric material is added to the viscoelastic matrix 24, the polymer piezoelectric material to be added to the above-described coating material may be dissolved. Alternatively, the polymer piezoelectric material to be added may be added to the above-described heated and melted viscoelastic material and may be heated and melted.

After the laminated body 10b in which the lower electrode 14 is included on the lower protective layer 18 and the piezoelectric layer 12 is formed on the lower electrode 14 is produced, the polarization process (polling) is preferably performed on the piezoelectric layer 12.

A method of polarization-processing the piezoelectric layer 12 is not particularly limited, and a known method is available. A method illustrated in FIGS. 4C and 4D is exemplified as a preferable polarization process method.

In this method, as illustrated in FIGS. 4C and 4D, a gap g of, for example, 1 mm is formed on an upper surface 12a of the piezoelectric layer 12 of the laminated body 10b, and a movable rod-like or wire-like corona electrode 50 is provided along the upper surface 12a. The corona electrode 50 and the lower electrode 14 are connected to a DC power supply 52.

Further, heating means for heating and holding the laminated body 10b, such as a hot plate, is prepared.

A DC voltage of a few kV, for example, 6 kV is applied between the lower electrode 14 and the corona electrode 50 from the DC power supply 52 in a state in which the piezoelectric layer 12 is heated and held on the laminated body 10b, for example, at a temperature of 100° C. by the heating means, causing corona discharge. Further, the corona electrode 50 is moved (scanned) along the upper surface 12a of the piezoelectric layer 12 in a state in which the gap g is maintained, and a polarization process of the piezoelectric layer 12 is performed.

In the polarization process using such corona discharge, known means of moving a rod-like object may be used for movement of the corona electrode 50. In the following description, the polarization process using the corona discharge is also referred to as a corona polling process.

Further, in the corona polling process, a method of moving the corona electrode 50 is not limited. That is, the corona electrode 50 may be fixed, moving mechanism that moves the laminated body 10b may be provided, and the laminated body 10b may be moved so as to perform the polarization process. For movement of the laminated body 10b, known means for moving a sheet-like object may be used.

Further, the number of corona electrodes 50 is not limited to 1, and the corona polling process may be performed using a plurality of corona electrodes 50.

Further, the polarization process is not limited to the corona polling process, and normal electric field polling in which a DC electric field is directly applied to a polarization process target is also available. However, when the normal electric field polling is performed, it is necessary for the upper electrode 16 to be formed prior to the polarization process.

Calendar processing of smoothing a surface of the piezoelectric layer 12 using a heating roller or the like may be performed prior to this polarization process. By applying the calendar processing, a thermal pressure bonding process to be described below can be performed smoothly.

On the other hand, a sheet-like object 10c in which the upper electrode 16 of the upper protective layer 20 is formed is prepared.

The sheet-like object 10c may be the upper electrode 16 divided into the respective regions by forming a copper thin film or the like using vacuum deposition or the like similarly to the above-described sheet-like object 10a, for example, by performing masking or the like on the surface of the upper protective layer 20. Alternatively, the sheet-like object 10c may be the upper electrode 16 divided into the respective regions by processing the same object as the sheet-like object 10a according to a material for forming the upper electrode 16. Alternatively, the upper electrode 16 divided into the respective segments may be produced by forming a silver paste or the like on the surface of the piezoelectric layer 12 using screen printing.

This sheet-like object 10c is laminated to the laminated body 10b subjected to the polarization process of the piezoelectric layer 12, with the upper electrode 16 directed to the piezoelectric layer 12, as illustrated in FIG. 4E.

Further, a laminated body of the laminated body 10b and the sheet-like object 10c is sandwiched between the lower protective layer 18 and the upper protective layer 20, and subjected to thermocompression bonding using a hot press apparatus, a heating roller, or the like to complete the conversion film 10 of the present invention as illustrated in FIGS. 1A and 1B.

In the conversion film 10 illustrated in FIGS. 1A and 1B and FIGS. 2A to 2H, a segment corresponding to the weight of the bit digit of the parallel PCM digital signal is configured to be sequentially directed from the center arranged in one direction to both outer sides in an arrangement direction.

In addition thereto, in the conversion film 10, various regions may be combined to constitute the segment. That is, in addition thereto, in the conversion film 10, various regions may be combined and grouped.

For example, the region 16a may form the first segment, the region 16b and the region 16c may be grouped through parallel coupling to form the second segment, and the regions 16d to 16g may be grouped through parallel coupling to form the third segment.

However, as in the conversion film 10 illustrated in FIG. 1B or the like, it is preferable to constitute the segment by sequentially performing weighting in both outer directions from the center since there is no uneven distribution of sound and more natural voice output can be achieved.

The conversion film 10 illustrated in FIGS. 1A and 1B is obtained by dividing, the upper electrode 16 of the conversion film 10 having a rectangular planar shape into regions arranged in one direction.

In addition thereto, various configurations are available in the conversion film of the present invention as long as the upper electrode (and/or the lower electrode) can be divided in the same area and into 2^{N-1} regions according to the maximum bit number N of the parallel PCM digital signal.

FIGS. 5A to 5H conceptually illustrate another example of the conversion film of the present invention. FIGS. 5A to 5H are top views, similar to FIG. 1B and FIGS. 2A to 2H.

In FIGS. 5A to 5H, an upper protective layer 20 is omitted in order to clearly illustrate a configuration, and a gap between respective regions is also omitted in order to simplify FIGS. 5A to 5H.

Further, a conversion film 30 illustrated in FIG. 5A or the like is the same as the conversion film 10 illustrated in FIGS. 1A and 1B in that a configuration in which a piezoelectric layer 12 is sandwiched between a lower electrode 14 and an upper electrode 32, and such a laminated body is sandwiched between a lower protective layer 18 and an upper protective layer 20 is adopted. Further, the lower electrode 14 is a common electrode that is common to respective divided regions of the upper electrode 32.

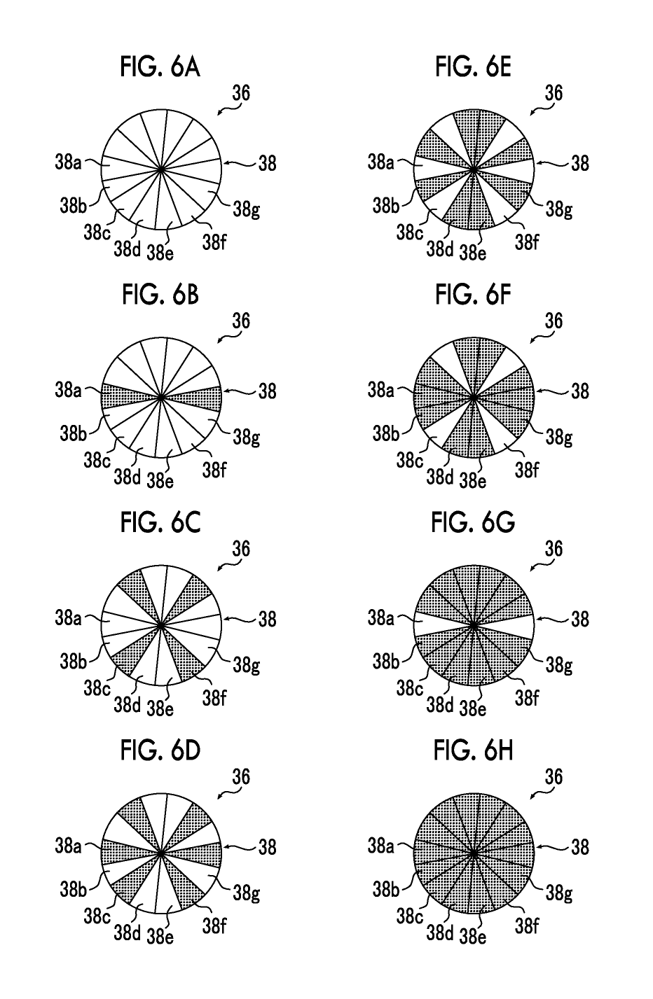

The same applies to the conversion film illustrated in FIGS. 6A to 6H to be described below.

The conversion film 30 is not limited to a conversion film having a circular planar shape, and a circular upper electrode 32 may be formed in a conversion film having a rectangular plane shape. Alternatively, conversely, a rectangular upper electrode may be formed in a circular conversion film.

The same applies to a conversion film illustrated in FIGS. 6A to 6H to be described below.

In the conversion film 30 illustrated in FIG. 5A or the like, the upper electrode 32 is circular and is divided at substantially the same angles radially from the center. The upper electrode 32 is divided into seven regions 32a to 32g having substantially the same area.

In the conversion film 30, each region forms a segment including the number of regions proportional to the weight of each bit digit of the parallel PCM digital signal of 3 bit digits to correspond to the output of 3 bits (8 gradations) through parallel coupling. That is, in the conversion film 30, the respective regions are grouped in the number proportional to the weight of each bit digit of the parallel PCM digital signal of 3 bit digits to correspond to the output of 3 bits.

Specifically, the region 32a forms the first segment as one region without being coupled in parallel to the other regions. The region 32d and the region 32f are coupled in parallel to form the second segment. Further, the region 32b, the region 32c, the region 32e, and the region 32g are coupled in parallel to form the third segment. That is, the first segment includes one region (2⁰), the second segment includes two regions (2¹), and the third segment includes four regions (2²).

Therefore, reproduction sound with eight gradations correctly subjected to the D/A conversion can be output by driving the segment corresponding to each bit digit with eight driving patterns according to the 3-bit parallel PCM digital signal.

That is, in a case where the parallel PCM digital signal is “0”, all of the first segment to the third segment c are not driven (0+0+0=0), as illustrated in FIG. 5A.

In a case where the parallel PCM digital signal is “1”, only the first segment, that is, the region 32a is driven (0+0+2⁰=1), as illustrated in FIG. 5B.

In a case where the parallel PCM digital signal is “2”, only the second segment, that is, the region 32d and the region 32f is driven (0+2¹+0=2), as illustrated in FIG. 5C.

In a case where the parallel PCM digital signal is “3”, the first segment, that is, the region 32a and the second segment, that is, the region 32d and the region 32f are driven (0+2¹+2⁰=3), as illustrated in FIG. 5D.

In a case where the parallel PCM digital signal is “4”, only the third segment, that is, the region 32b, the region 32c, the region 32e, and the region 32g is driven (2²+0+0=4), as illustrated in FIG. 5E.

In a case where the parallel PCM digital signal is “5”, the first segment, that is, the region 32a and the third segment, that is, the region 32b, the region 32c, the region 32e, and the region 32g are driven (2²+0+2⁰=5), as illustrated in FIG. 5F.

In a case where the parallel PCM digital signal is “6”, the second segment, that is, the region 32d and the region 32f and the third segment, that is, the region 32b, the region 32c, the region 32e, and the region 32g are driven (2²+2¹+0=6), as illustrated in FIG. 5G.

Further, in a case where the parallel PCM digital signal is “7”, the first segment, that is, the region 32a, the second segment, that is, the region 32d and the region 32f, and the third segment, that is, the region 32b, the region 32c, the region 32e, and the region 32g are all driven (2²+2¹+2⁰=7), as illustrated in FIG. 5H.

Thus, audio output subjected to D/A conversion with intensity of 8 gradations including 0 to 7 gradations according to the 3-bit parallel PCM digital signal can be performed.

FIGS. 6A to 6H conceptually illustrate another example of the conversion film of the present invention. FIGS. 6A to 6H are top views, similar to FIG. 1B or FIGS. 2A to 2H.

In the conversion film 36 illustrated in FIG. 6A or the like, the upper electrode 38 is circular. This circular upper electrode 38 is also divided into fan-shapes radially from a center of the circle. Here, the upper electrode 38 is divided into 14 small fan-shaped regions in straight lines passing through the center of the circle, and one area is formed from two small regions that are point symmetrical to the center of the circle.

In the conversion film 36, each region forms a segment including the number of regions proportional to the weight of each bit digit of the parallel PCM digital signal of 3 bit digits to correspond to the output of 3 bits (8 gradations) through parallel coupling. That is, in the conversion film 36, the respective regions are grouped in the number proportional to the weight of each bit digit of the parallel PCM digital signal of 3 bit digits to correspond to the output of 3 bits.

Specifically, the region 38a forms the first segment as one region without being coupled in parallel to the other regions. The region 38c and the region 38f are coupled in parallel to form the second segment. Further, the region 38b, the region 38d, the region 38e, and the region 38g are coupled in parallel to form the third segment. That is, the first segment includes one region (2⁰), the second segment includes two regions (2¹), and the third segment includes four regions (2²).

Therefore, reproduction sound with eight gradations correctly subjected to the D/A conversion can be output by driving the segment corresponding to each bit digit with eight driving patterns according to the 3-bit parallel PCM digital signal.

That is, in a case where the parallel PCM digital signal is “0”, all of the first segment to the third segment are not driven (0+0+0=0), as illustrated in FIG. 6A.

In a case where the parallel PCM digital signal is “1”, only the first segment, that is, the region 38a is driven (0+0+2⁰=1), as illustrated in FIG. 6B.

In a case where the parallel PCM digital signal is “2”, only the second segment, that is, the region 38c and the region 38f is driven (0+2¹+0=2), as illustrated in FIG. 6C.

In a case where the parallel PCM digital signal is “3”, the first segment, that is, the region 38a and the second segment, that is, the region 38c and the region 38f are driven (0+2¹+2⁰=3), as illustrated in FIG. 6D.

In a case where the parallel PCM digital signal is “4”, only the third segment, that is, the region 38b, the region 38d, the region 38e, and the region 38g is driven (2²+0+0=4), as illustrated in FIG. 6E.

In a case where the parallel PCM digital signal is “5”, the first segment, that is, the region 38a and the third segment, that is, the region 38b, the region 38d, the region 38e, and the region 38g are driven (2²+0+2⁰=5), as illustrated in FIG. 6F.

In a case where the parallel PCM digital signal is “6”, the second segment, that is, the region 38c and the region 38f and the third segment, that is, the region 38b, the region 38d, the region 38e, and the region 38g are driven (2²+2¹+0=6), as illustrated in FIG. 6G.

Further, in a case where the parallel PCM digital signal is “7”, the first segment, that is, the region 38a, the second segment, that is, the region 38c and the region 38f, and the third segment, that is, the region 38b, the region 38d, the region 38e, and the region 38g are all driven (2²+2¹+2⁰=7), as illustrated in FIG. 6H.

Thus, audio output subjected to D/A conversion with intensity of 8 gradations including 0 to 7 gradations according to the 3-bit parallel PCM digital signal can be performed.

In the conversion film 30 illustrated in FIG. 5A or the like, sound is likely to be heard unevenly since each segment of the upper electrode 32 is unevenly distributed.

On the other hand, in the conversion film 36 illustrated in FIG. 6A or the like, there is no uneven distribution of sound and more natural sound output can be achieved since the respective regions of the upper electrode 38 are formed of two small regions that are point symmetrical to the center.

The conversion film (digital speaker) of the present invention is not limited to 3-bit 8-gradation output as in the illustrated example. That is, if the upper electrode (and/or the lower electrode) is divided into 2^{N-1} regions to correspond to the maximum bit number N and the number of regions grouped through parallel connection is increased by 2ⁿ times according to the bit digits, it is possible to cope with output of various numbers of bits.

For example, in the case of 8 bits, if the upper electrode is divided into 255 (2⁸−1) regions and the regions are coupled in parallel and grouped to form eight segments so that the number is increased by 2ⁿ, the parallel PCM digital signal of 8 bit digits can be reproduced.

Therefore, in this case, the number of regions in the segment of which the number of regions is maximum is 2⁸−1 times the number of regions in the segment of which the number of regions is minimum. In other words, in this case, the number of regions in the segment of which the number of regions is maximum is 2⁸−1 times the number of regions in a segment representing the parallel PCM digital signal 1.

In the above example, in the conversion film of the present invention, signal intensities, that is, the driving voltages input to the respective regions are the same and the plurality of regions are coupled in parallel, so as to perform weighting according to each bit digit using the area. However, in the conversion film of the present invention, the driving voltages supplied to the respective regions may not necessarily be the same.

That is, high-gradation audio output can be achieved in the limited number of regions by complementing or extending the weighting using the area by performing weighting with the driving voltage of each region.

Alternatively, sound output subjected to D/A-conversion according to the parallel PCM digital signal may be performed by increasing the voltage applied to each segment (region) by 2ⁿ in proportion to the weight of each bit digit of the parallel PCM digital signal without performing weighting based on an area. The voltage applied to each segment is a voltage of pulse waves.

That is, in the conversion film of the present invention in which the upper electrode and/or the lower electrode is divided into a plurality of regions having the same area, and audio output subjected to D/A conversion according to the parallel PCM digital signal is performed, weighting proportional to the weight of each bit digit of the parallel PCM digital signal may be performed with the number of regions, that is, the area of each segment or may be performed with the voltage supplied to each region, that is, each segment.

In a case where the weighting proportional to the weight of each bit digit of the parallel PCM digital signal is performed with a voltage supplied to each segment, one region becomes one segment, and the number of segments becomes the maximum bit number N.

For example, in the conversion film 10 illustrated in FIG. 1A and FIG. 1B, since the upper electrode 16 is divided into the seven regions including regions 16a to 16g, D/A-converted audio output of 128 gradations from 0 to 127 gradations corresponding to the 7-bit parallel PCM digital signal can be performed.

For example, a voltage of 1 V (2⁰) is set to be supplied with the region 16a as a 1 bit digit, a voltage of 2 V (2¹) is set to be supplied with the region 16b as 2 bit digits, a voltage of 4 V (2²) is set to be supplied with the region 16c as 3 bit digits, a voltage of 8 V (2³) is set to be supplied with the region 16d as 4 bit digits, . . . , a voltage of 64 V (2⁶) is set to be supplied with the region 16g as 7 bit digits

Moreover, for example, by driving the region 16a and the region 16d in a case where the parallel PCM digital signal is “5”, driving the region 16b and the region 16d in a case where the parallel PCM digital signal is “10”, driving the region 16a and the region 16g in a case where the parallel PCM digital signal is “65”, D/A-converted audio output of 128 gradations corresponding to the 7-bit parallel PCM digital signal may be performed.

Although the electro-acoustic conversion film and the digital speaker of the present invention have been described in detail, it is understood that the present invention is not limited to the above-described embodiments and various improvements or modifications may be performed without departing from the scope and spirit of the present invention.

### EMBODIMENTS

Hereinafter, the present invention will be described in greater detail using specific embodiments of the present invention.

### Embodiment 1

The conversion film 10 of the present invention illustrated in FIGS. 1A and 1B was prepared using the method illustrated in FIGS. 4A to 4E described above.

First, cyanoethylated PVA (CR-V manufactured by Shin-Etsu Chemical Co., Ltd.) was dissolved in dimethyl formamide (DMF) in a compositional ratio described below. Then, the PZT particles was added to this solution in the compositional ratio described below, dispersed by a propeller mixer (number of revolutions: 2000 rpm), and a coating material for forming the piezoelectric layer 12 was prepared.

| | |
|---|---|
| PZT particles | 300 parts by weight |
| Cyanoethylated PVA | 30 parts by weight |
| DMF | 70 parts by weight |

PZT particles obtained by sintering a commercially available PZT raw material powder at 1000° C. to 1200° C. and then crushing and classifying the powder so that an average particle size is 5 μm was used.

On the other hand, the sheet-like objects 10a and 10c obtained by vacuum-depositing a thin copper film having a thickness of 0.1 μm on a PET film having a thickness of 4 μm was prepared. That is, in this example, the lower electrode 14 and the upper electrode 16 were copper deposition thin films having a thickness of 0.1 m, and the lower protective layer 18 and the upper protective layer 20 were PET films having a thickness of 4 μm.

A size of the sheet-like object 10a and the sheet-like object 10c is a size such that a size of a vibration surface when incorporated into a speaker is 210×300 mm (A4 size).

The sheet-like object 10c was used to form the upper electrode 16 divided into the seven regions 16a to 16g having the same area which are arranged in one direction, as illustrated in FIG. 1A using a mask deposition method. The gap 16s between the respective regions was 5 mm.

Further, the region 16a forms the first segment without being coupled in parallel to the other regions, the region 16c and the region 16e are coupled in parallel to form the second segment, and the region 16a, the region 16b, the region 16f, and the region 16g are coupled in parallel to form the third segment.

The lower electrode 14 (copper deposition thin film) of the sheet-like object 10a was coated with a coating material for forming the previously prepared piezoelectric layer 12 using a slide coater. Coating with the coating, material was performed so that a thickness of a coating film after drying was 40 μm.

Then, the object obtained by coating the sheet-like object 10a with the coating material was heated and dried on a hot plate at 120° C. so that DMF was evaporated. Thus, the laminated body 46b in which the lower copper electrode 14 was included on the PET lower protective layer 18, and the piezoelectric layer 12 having a thickness of 40 μm was formed thereon was prepared.

The piezoelectric layer 12 of this laminated body 46b was subjected to the polarization process by the above-described corona polling illustrated in FIGS. 4C and 4D. The polarization process was performed by setting the temperature of the piezoelectric layer 12 to 100° C. and applying a DC voltage of 6 kV between the lower electrode 14 and the corona electrode 50 to cause corona discharge.

The sheet-like object 10c in which the upper electrode 16 divided into the respective regions is formed was laminated on the laminated body 46b subjected to the polarization process, with the upper electrode 16 (copper thin film side) directed to the piezoelectric layer 12.

Then, a laminated body of the laminated body 46b and the sheet-like object 46c was subjected to thermocompression bonding at 120° C. using a laminator apparatus. Accordingly, the piezoelectric layer 12 was bonded to the lower electrode 14 and the upper electrode 16, such that the conversion film 10 was prepared.

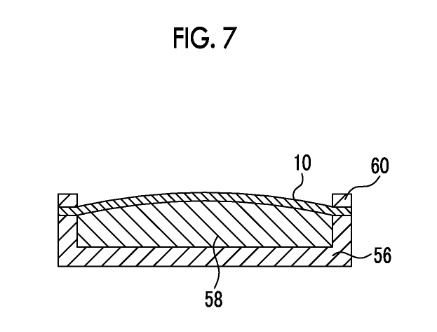

A rectangular box-shaped case 56 of which one face was opened as illustrated in FIG. 7 was prepared. The case 56 was formed of plastic, a size of an opening is 200×290 mm, and a depth is 9 mm.

As a viscoelastic support of the conversion film 10, a glass wool 58 having a height prior to assembly of 25 mm and a density of 32 kg/m³ was housed in the case 56.

The conversion film 10 was disposed to cover the opening of the case 82 and a periphery thereof was fixed by a frame body 60, and an appropriate tension and curvature was applied to the conversion film 10 by the viscoelastic support 84, such that the speaker as illustrated in FIG. 8 was prepared.

[Speaker Performance Test]

A 3-bit parallel PCM digital signal was input to the first segment a, the second segment b, and the third segment c of the produced speaker, and sound quality was evaluated using sensory evaluation.

The evaluation was performed through sensory evaluation by 20 persons, a case in which the number of persons for which clarity or gradation of sound was evaluated as being good is 18 or more was regarded as evaluation A, a case in which the number of persons is 16 or more and less than 18 was regarded as evaluation B, and a case in which the number of persons is less than 16 was regarded as evaluation C.

The evaluation was A.

### Embodiment 2

In the following compositional ratio, polyvinyl acetate (manufactured by Aldrich) was dissolved in dimethylformamide (DMF). Then, PZT particles were added to this solution in the following compositional ratio and dispersed with a propeller mixer (number of revolutions: 2000 rpm) to prepare a coating material for forming the piezoelectric layer 12.

| | |
|---|---|
| PZT particles | 200 parts by weight |
| Poly vinyl acetate | 20 parts by weight |
| DMF | 80 parts by weight |

The PZT particles were produced, in the same manner as in Embodiment 1.

The conversion film 10 was produced in the same manner as in Embodiment 1 except that the piezoelectric layer 12 was formed using the coating material.

The same speaker as in Embodiment 1 was produced and evaluated in the same manner as in Embodiment 1. As a result, the evaluation was B.

### Comparative Example 1

The upper electrode and the lower electrode were respectively formed at the same positions as in Embodiment 1 through vacuum evaporation using commercially available PVDF having a thickness of 50 μm as a speaker vibration plate, and a conversion film was produced.

The same speaker as in Embodiment 1 was produced and evaluated in the same manner as in Embodiment 1. As a result, the evaluation was C.

It can be seen from the result of Embodiment 1 that in the conversion film 10 of the present invention, there is no reverberation, there is no crosstalk (interference) between the segments, and the parallel PCM digital signal can be suitably reproduced.

Further, in Embodiment 2 using polyvinyl acetate in place of cyanoethylated PVA as a polymer material for forming the piezoelectric layer 12, since a relative dielectric constant at room temperature (25° C.) of the polymer material is lower than that in Embodiment 1, energy conversion efficiency is low and a volume is low, but clarity or gradation of sound is more excellent than in Comparative example. The relative dielectric constant at room temperature of the polymer material is approximately 20 in Embodiment 1 and approximately 3 in Embodiment 2.

On the other hand, in the conversion film of Comparative example 1 using PVDF as a speaker vibration plate, if the parallel PCM digital signal is input, the parallel PCM digital signal cannot be reproduced with high quality due to occurrence of reverberation or crosstalk.

The effects of the present invention are apparent from the above results.

### EXPLANATION OF REFERENCES

10, 30, 36: (electro-acoustic) conversion film
12: piezoelectric body
14: lower (thin film) electrode
16, 32, 38, 42: upper (thin film) electrode
16a to 16g, 32a to 32g, 38a to 38g: region
16s: gap
50: corona electrode
52: DC power supply
56: case
58: glass wool
60: frame

What is claimed is:

1. An electro-acoustic conversion film, comprising:
a polymer composite piezoelectric body formed by dispersing piezoelectric particles in a viscoelastic matrix formed of a polymer material having viscoelasticity at room temperature, and thin-film electrodes provided on both surfaces of the polymer composite piezoelectric body,
wherein at least one of the thin-film electrodes is divided into a plurality of regions having the same area, and the respective regions are coupled in parallel and grouped to correspond to a weight of each bit digit of a parallel PCM digital signal, and
wherein a loss tangent (Tan δ) at 100 Hz to 10 kHz at a temperature of 0° C. to 50° C. is 0.09 to 0.35.

2. The electro-acoustic conversion film according to claim 1,
wherein a grouping in which the respective regions are grouped to correspond to the weight of the each bit digit of the parallel PCM digital signal is performed so that the number of regions increases by 2ⁿ (n is a natural number increasing by 1 and including 0) to correspond to the weight of the bit digit of the parallel PCM digital signal.

3. The electro-acoustic conversion film according to claim 1,
wherein a division in which the respective regions are divided into the plurality of regions having the same area is performed so that the plurality of regions are arranged in one direction, and a grouping in which the respective regions are grouped to correspond to the weight of the each bit digit of the parallel PCM digital signal is performed so that the regions are sequentially directed from a center in the arrangement direction to both outer sides in the arrangement direction.

4. The electro-acoustic conversion film according to claim 1,
wherein the plurality of divided regions of the electrode are a plurality of regions divided at the same angles radially from the center.

5. The electro-acoustic conversion film according to claim 4,
wherein a division in which the respective regions are divided into the plurality of regions having the same area is performed in straight lines passing through the center, and the region includes two small regions that are point symmetrical to the center.

6. The electro-acoustic conversion film according to claim 1, further comprising:
protective layers formed on both surfaces of the thin-film electrode.

7. The electro-acoustic conversion film according to claim 1,
wherein a maximum value at which a loss tangent (Tan δ) at a frequency of 1 Hz from dynamic viscoelasticity measurement of the polymer material is 0.5 or more is present in a temperature range of 0° C. to 50° C.

8. The electro-acoustic conversion film according to claim 1,
wherein a storage elastic modulus (E′) at a frequency of 1 Hz from dynamic viscoelasticity measurement of the electro-acoustic conversion film is 10 to 30 GPa at 0° C. and 1 to 10 GPa at 50° C.

9. The electro-acoustic conversion film according to claim 1,
wherein glass transition temperature at a frequency of 1 Hz of the polymer material is 0° C. to 50° C.

10. The electro-acoustic conversion film according to claim 1,
wherein the polymer material has a cyanoethyl group.

11. The electro-acoustic conversion film according to claim 10,
wherein the polymer material is cyanoethylated polyvinyl alcohol.

12. A digital speaker using the electro-acoustic conversion film according to claim 1.
